(19) United States
(12) Patent Application Publication
(10) Pub. No.: US 2026/0150384 A1
(43) Pub. Date: May 28, 2026

(54) MONOLITHIC INTEGRATION OF HEMT DEVICES OF NORMALLY-OFF TYPE WITH HEMT DEVICES OF NORMALLY-ON TYPE

(71) Applicant: STMICROELECTRONICS INTERNATIONAL N.V., Geneva (CH)

(72) Inventors: Paolo COLPANI, Agrate Brianza (IT); Luisito LIVELLARA, Cernusco sul Naviglio (IT)

(21) Appl. No.: 19/376,100

(22) Filed: Oct. 31, 2025

(30) Foreign Application Priority Data
Nov. 25, 2024 (IT) 102024000026469

(51) Int. Cl. H10D 84/01; H10D 30/01; H10D 30/47; H10D 84/84

(52) U.S. Cl. CPC H10D 84/0163; H10D 30/015; H10D 30/471; H10D 84/84

(57) ABSTRACT

A method for manufacturing a semiconductor die including an E-mode HEMT device at a first region of the semiconductor die and a D-mode MIS-HEMT device at a second region of the semiconductor die is provided. An example method includes: forming, on a heterostructure, a doped gate region of the E-mode HEMT device; forming a dielectric layer on the heterostructure and on the doped gate region; forming an insulating layer on the dielectric layer; forming a first gate opening exclusively at the second region, etching the first insulating layer but not the dielectric layer; forming a second gate opening, etching the first insulating layer and the dielectric layer exclusively at the doped gate region; and filling the first and the second gate openings with conductive material to form respective gate terminals of the D-mode MIS-HEMT and E-mode HEMT devices.

### CROSS REFERENCE TO RELATED APPLICATION(S)

This application claims the priority benefit of Italian patent application number 102024000026469, filed on Nov. 25, 2024, entitled “INTEGRAZIONE MONOLITICA DI DISPOSITIVI HEMT DI TIPO NORMALMENTE SPENTO CON DISPOSITIVI HEMT DI TIPO NORMALMENTE ACCESO”, which is hereby incorporated by reference to the maximum extent allowable by law.

### TECHNICAL FIELD

The present disclosure relates to a manufacturing method of a semiconductor die, and to the semiconductor die thereof; in particular, the semiconductor die integrates a HEMT device of normally-off type and a HEMT device of normally-on type with reduced degradation of the ON-state resistance.

### BACKGROUND

HEMT (High-Electron-Mobility Transistors) transistors with heterostructure are known, in particular of gallium nitride (GaN) and aluminum gallium nitride (AlGaN), at whose interface a conductive channel, in particular a two-dimensional electron gas (2DEG), may be formed. For example, HEMT transistors are appreciated for use as high-frequency switches and as power switches, by virtue of their high breakdown threshold and high electron mobility and charge carrier density of their conductive channel. Furthermore, the high current density in the conductive channel of the HEMT transistor allows a low ON-state resistance (or simply, RON) of the conductive channel to be obtained.

In known depletion-mode HEMT or D-mode HEMT devices, wherein a gate electrode extends above, and in contact with, the AlGaN/GaN heterostructure, the transistor is normally-on, since a high density of charge carriers is present in the channel even in the absence of a gate voltage applied to the heterostructure.

For safety reasons and to simplify driving circuits of HEMT devices, thus favoring their use in industrial applications, enhancement-mode HEMT or E-mode HEMT devices have been introduced, wherein the transistor is normally-off. Several approaches have been proposed to obtain normally-off HEMTs, such as for example E-mode HEMTs with a recessed gate or a p-GaN gate.

The integration of D-mode HEMT devices with E-mode HEMT devices on single dice is known. On dice wherein D-mode HEMT devices are integrated with E-mode HEMT devices, the Applicant has observed reduced performances of the D-mode HEMT devices compared to dice wherein only D-mode HEMT devices are present.

The reduction in performances of D-mode HEMT devices, when integrated with E-mode HEMT devices on a single die, is attributed to damage to a top surface of the heterostructure at the D-mode HEMT devices. In particular, in D-mode HEMT devices with an AlGaN/GaN heterostructure, formed by an AlGaN layer superimposed on a GaN layer, a top surface of the AlGaN layer opposite to the interface between AlGaN and GaN may be damaged during the manufacturing process of the die. The damage to the top surface of the AlGaN layer is caused by process steps carried out to concurrently open gate contacts of the D-mode HEMT devices and gate contacts of the E-mode HEMT devices. Such process steps include, for example, lithography and selective etching steps, followed by a metal deposition step.

The surface of the AlGaN layer, following the opening of the gate contact or a non-optimal deposition of the metal, may be damaged in its chemical structure and/or in its thickness and/or may incorporate impurities causing a localized reduction of the electronic density of the 2DEG zone below the gate region. As a result, this may cause a restriction of the conduction channel that degrades the negative switch-off threshold of the device (which remains at negative values, but close to zero). It is therefore appropriate to disturb the chemical-physical characteristics of the AlGaN layer as little as possible in manufacturing the D-mode HEMT device.

A need is therefore felt to provide a manufacturing method of a semiconductor die and a semiconductor die thereof such as to overcome the drawbacks of the prior art.

### BRIEF SUMMARY

The present disclosure relates to manufacturing method of a semiconductor die and to a semiconductor die thereof.

In accordance with some embodiments of the present disclosure, a method for manufacturing a semiconductor die including an E-mode HEMT or E-mode MIS-HEMT device at a first region of the semiconductor die and a D-mode MIS-HEMT device at a second region of the semiconductor die, the first region and the second region being at a distance from each otheris provided. An example method includes: forming a heterostructure on a substrate of the semiconductor die, at both the first region and the second region; forming, on the heterostructure, a doped gate region of the E-mode HEMT or E-mode MIS-HEMT device, at the first region; forming a dielectric layer in the first region on the heterostructure and on the doped gate region and, concurrently, in the second region on the heterostructure, the dielectric layer being of a first material; forming a first insulating layer on the dielectric layer, at the first region and the second region, of a second material that may be selectively etched with respect to the first material; forming a first gate opening by etching the first insulating layer throughout an entire thickness and exposing the dielectric layer underlying, at the second region; forming a second gate opening by etching the first insulating layer throughout the entire thickness, at the doped gate region; and forming a gate conductive terminal of the D-mode MIS-HEMT device in the first gate opening and, concurrently, forming a respective gate conductive terminal of the E-mode HEMT or E-mode MIS-HEMT device in the second gate opening.

In various embodiments, forming the second gate opening further includes, after etching the first insulating layer, etching, throughout the entire thickness, the dielectric layer exclusively at the doped gate region, exposing a portion of the doped gate region.

In various embodiments, the method further includes: forming, concurrently at the first region and the second region of the semiconductor die, a second insulating layer on the first insulating layer and at least partly superimposed on the doped gate region; wherein the second insulating layer is of a third material that may be selectively etched with respect to the second material; wherein forming the first gate opening further including etching the second insulating layer throughout the entire thickness, at the second region, partly exposing the first insulating layer; and wherein forming the second gate opening further including etching the second insulating layer throughout the entire thickness, at the first region and the doped gate region, partly exposing the first insulating layer.

In various embodiments, forming the first gate opening is performed before forming the second gate opening and includes: depositing a first mask layer over the semiconductor die concurrently at the first region and the second region; removing selective portions of the first mask layer exclusively at the second region, wherein etching the first insulating layer for forming the first gate opening being performed at the selective portions removed of the first mask layer; wherein forming the second gate opening includes: depositing a second mask layer over the semiconductor die concurrently at the first region and the second region and within the first gate opening; and removing selective portions of the second mask layer exclusively at the doped gate region, wherein etching the first insulating layer forming the second gate opening being performed at the selective portions removed of the second mask layer.

In various embodiments, forming the second gate opening is performed before forming the first gate opening and includes: depositing a first mask layer over the semiconductor die concurrently at the first region and the second region; removing selective portions of the first mask layer exclusively at the doped gate region, wherein etching the first insulating layer forming the second gate opening being performed at the selective portions removed of the first mask layer; forming the first gate opening includes: depositing a second mask layer over the semiconductor die concurrently at the first region and the second region and within the second gate opening; and removing selective portions of the second mask layer exclusively at the second region, wherein etching the first insulating layer forming the first gate opening being performed at the selective portions removed of the second mask layer.

In various embodiments, the method further includes: forming first conduction terminals of the E-mode HEMT or E-mode MIS-HEMT device, including: forming a first trench and a second trench at respective opposite sides of the doped gate region removing selective portions of the first insulating layer and the dielectric layer, reaching the heterostructure; filling the first trench and the second trench with at least one first metal layer; and concurrently, forming second conduction terminals of the D-mode MIS-HEMT device, including: forming a third trench and a fourth trench in the second region of the semiconductor die removing selective portions of the first insulating layer and of the dielectric layer, reaching the heterostructure; and filling the third trench and the fourth trench with the at least one first metal layer.

In various embodiments, forming the first conduction terminals and the second conduction terminals is performed before forming the first gate opening and forming the second gate opening; the first conduction terminals of the E-mode HEMT or E-mode MIS-HEMT device include a source terminal and a drain terminal; and the method further includes forming a field plate conductive layer over the first insulating layer between the doped gate region and the drain terminal.

In various embodiments, etching the second insulating layer to form the first gate opening is performed exclusively at the second region; and etching the second insulating layer to form the second gate opening is performed exclusively at the first region.

In various embodiments, forming the gate conductive terminal of the D-mode MIS-HEMT device and the gate conductive terminal of the E-mode HEMT or E-mode MIS-HEMT device includes depositing conductive material in the first gate opening until it reaches and contacts the dielectric layer and, concurrently, depositing the conductive material in the second gate opening until it reaches and contacts the doped gate region.

In accordance with some embodiments of the present disclosure, a semiconductor die including an E-mode HEMT or E-mode MIS-HEMT device at a first region of the semiconductor die and a D-mode MIS-HEMT device at a second region of the semiconductor die, the first region and second region being at a distance from each other is provided. An example semiconductor includes: a heterostructure on a substrate of the semiconductor die, at both the first region and the second region; a doped gate region of the E-mode HEMT or E-mode MIS-HEMT device on the heterostructure, at the first region; a dielectric layer on the heterostructure and on the doped gate region at the first region and on the heterostructure at the second region, the dielectric layer being of a first material; a first insulating layer on the dielectric layer, at the first region and the second region, of a second material which may be selectively etched with respect to the first material; a gate conductive terminal of the D-mode MIS-HEMT device, extending through the first insulating layer and in direct contact with the dielectric layer at the second region; and a respective gate conductive terminal of the E-mode HEMT or E-mode MIS-HEMT device, extending through the first insulating layer and the dielectric layer, in electrical contact with the doped gate region.

### BRIEF DESCRIPTION

For a better understanding of the present disclosure, some embodiments thereof are now described, purely by way of non-limiting example, with reference to the attached drawings, wherein:

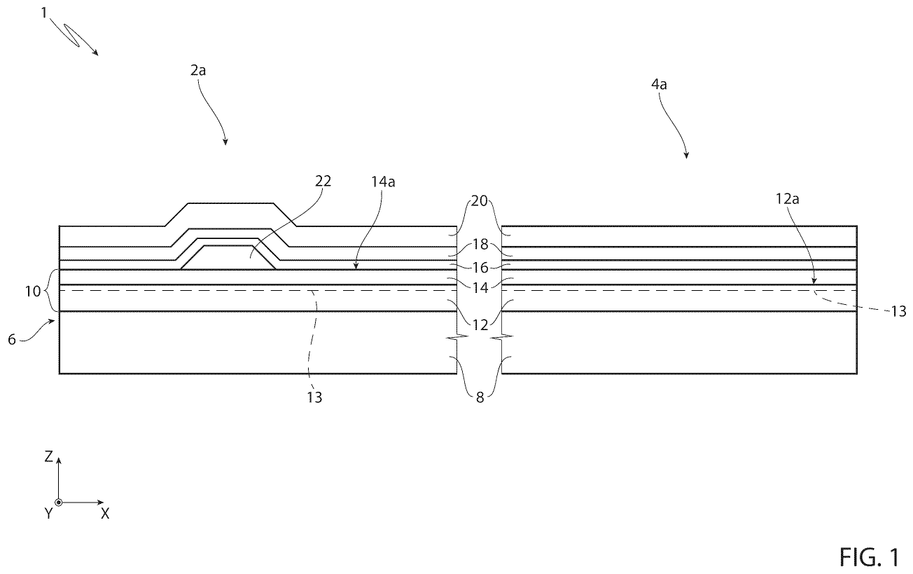

FIGS. 1-9 illustrate, in a lateral sectional view, a die including an E-mode HEMT device and a D-mode MIS-HEMT device, in respective manufacturing steps and according to one embodiment of the present disclosure;

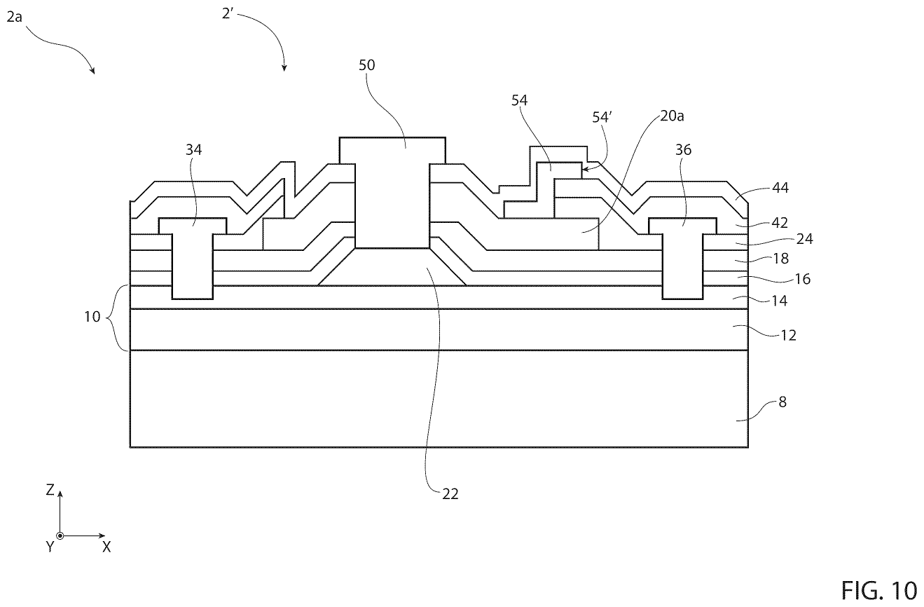

FIG. 10 illustrates, in a lateral sectional view, an E-mode HEMT device according to a further embodiment of the present disclosure; and

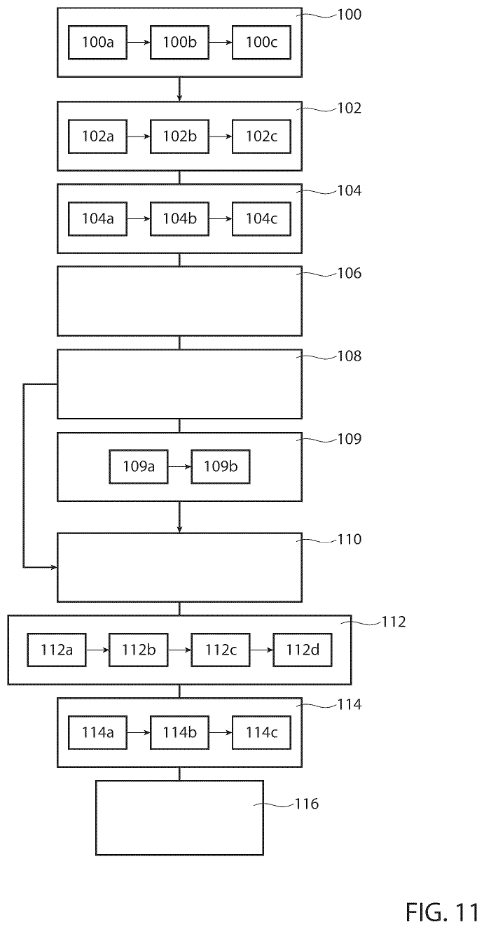

FIG. 11 illustrates, by means of a block diagram, steps of the manufacturing method of FIGS. 1-9 and 10.

### DETAILED DESCRIPTION OF THE DRAWINGS

According to one aspect of the present disclosure, a manufacturing process of a die 1 is described comprising at least one E-mode HEMT transistor and at least one D-mode HEMT transistor integrated on the die 1, wherein the manufacturing of the two types of transistors occurs concurrently, and without degrading the performances of the D-mode HEMT devices. In particular, the present disclosure comprises integrating on the same die 1 an E-mode HEMT device 2, in particular a HEMT device with a “p-Gan gate” doped gate, and a D-mode HEMT device 4 having a structure of the gate electrode comprising a stack of metal/insulator/semiconductor (MIS) or metal/dielectric/semiconductor type materials, also known as D-mode MIS-HEMTs. In the context of the present disclosure, the acronym MIS is used to indicate both a metal/insulator/semiconductor stack and a metal/dielectric/semiconductor stack.

The E-mode HEMT 2 and D-mode MIS-HEMT 4 devices integrated on the same die 1 may be configured to operate, in use, as power devices (for example with operating voltages in a range of 50V-150V, but also higher voltage classes, for example 650V) or as low-voltage circuit elements (for example with operating voltages (gate-drain voltages) in a range of 3V-15V), in respective embodiments.

With reference to FIGS. 1-9 and 11, manufacturing steps of the die 1 comprising the co-integrated E-mode HEMT device 2 and D-mode MIS-HEMT device 4 are now described, limitedly to the manufacturing of elements useful for understanding the present disclosure and according to a non-limiting embodiment of the present disclosure.

FIGS. 1-9 are represented in a triaxial system of axes X, Y, Z orthogonal to each other, in lateral section on the XZ plane. In particular, FIGS. 1-9 illustrate a first region 2a adapted to accommodate the E-mode HEMT device 2 and a second region 4a adapted to accommodate the D-mode MIS-HEMT device 4, at a distance from each other on the XY plane.

With reference to FIG. 1, the die 1 includes a solid body 6, which in turn comprises a substrate 8 and a heterostructure 10 extending over the substrate 8.

The substrate 8 is for example of silicon (Si), or silicon carbide (SiC) or sapphire (Al₂O₃), or GaN. The substrate 8 may alternatively be of the SOI (“Silicon Over Insulator”) type. The substrate 8 may include a buffer layer (not shown in FIG. 1) and a p-type doped-GaN buried layer (not shown in FIG. 1) extending on the buffer layer and on which the heterostructure 10 extends.

The heterostructure 10 includes, for example, a channel layer 12 extending in contact with a surface 8a of the substrate 8, and a barrier layer 14 extending on the channel layer 12 and in contact with a surface 12a of the channel layer 12. Thus, the channel layer 12 is interposed between the substrate 8 and the barrier layer 14. The conductive channel, in particular the two-dimensional electron gas (2DEG), is formed, in use, at an interface 13 between the channel layer 12 and the barrier layer 14.

The channel layer 12 is for example of gallium nitride (GaN) of intrinsic type (that is undoped or having impurities, such as carbon, resulting, unintentionally, from the manufacturing process); the barrier layer 14 is for example of undoped aluminum gallium nitride (AlGaN).

The channel layer 12 has for example a thickness, along the Z axis, comprised between 300 nm and 1 μm, in particular between 400 nm and 600 nm. The barrier layer 14 has for example a thickness, along the Z axis, comprised between 10 nm and 20 nm, for example 14 nm.

The die 1 further includes a doped gate region 22, for example of gallium nitride (GaN) that is P-type doped (for example with manganese), with a dopant concentration comprised, for example, between 5·10¹⁸ at/cm³ and 4·10¹⁹ at/cm³. The doped gate region 22 extends in the first region 2a of the die 1, on a surface 14a of the barrier layer 14 opposite to the surface 12a along the Z axis.

The doped gate region 22 has a thickness along the Z axis comprised, for example, between 50 nm and 200 nm, for example equal to 100 nm, and has an extension along the X axis comprised, for example, between 0.4 μm and 1.5 μm, and has an extension along the Y axis comprised, for example, between 50 μm and 1 mm. This structure may be repeated multiple times to withstand currents having high values.

As is known, the doped gate region 22 modifies the band diagram of the heterostructure 10 such that, in the absence of a voltage applied to the doped gate region 22, the 2DEG is depleted in the area below the doped gate region 22. Consequently, in the absence of such a gate voltage, the conductive channel is interrupted below the doped region 22.

The steps of forming the solid body 6 (including the substrate 8 and the heterostructure 10) and the doped gate region 22 are known per se, and therefore not described in detail.

With joint reference to FIGS. 1 and 11, a step 100 is performed including successive depositions of dielectric or insulating layers. In detail, a step 100a of depositing a first dielectric layer 16 is performed on the surface 14a of the barrier layer 14 and on the doped gate region 22. Step 100a is performed for example through Atomic Layer Deposition, ALD, deposition techniques, which may be of a thermal or plasma-assisted type.

A step 100b of depositing a first insulating layer 18 is then performed on the first dielectric layer 16 followed by a step 100c of depositing a second insulating layer 20 that extends on the first insulating layer 18. These three layers form a dielectric passivation. Thermal ALD or plasma deposition techniques may be used for all three depositions of the layers 16, 18 and 20 and, where the chosen thicknesses allow it, also CVD deposition (thermal or plasma-assisted). Both depositions of steps 100b and 100c occur on both the first region 2a of the die 1 (on which the E-mode HEMT device 2 will be formed) and on the second region 4a of the die 1 (on which the D-mode MIS-HEMT device 4 will be formed).

In an alternative embodiment, the first insulating layer 18 may be omitted. In this case, the second insulating layer 20 extends in contact with the dielectric layer 16.

The first dielectric layer 16 and the first insulating layer 18 are of respective materials different from each other and in particular chosen such that the material of the first insulating layer 18 may be etched (with wet or dry removal techniques) selectively with respect to the material of the first dielectric layer 16, for example by means of wet etchings (such as for example HF, HCl, H₂PO₄) or dry etchings (by means of plasma-assisted dry removal processes). In one embodiment, the expression “different” materials means that the two materials of the layers 16 and 18 have a respective chemical (or stoichiometric) composition containing at least one main component that is different from each other. The expression “main component” means that such component has a stoichiometric percentage greater than 20% in the chemical composition, preferably 25% in the chemical composition. Typically, the etching selectivity between two materials depends both on the chemical composition of the material (i.e., different materials are sensitive to etching with different acids) and on the type of bonds that are established between the atoms/molecules of the structure of the specific material.

For example, the first dielectric layer 16 is of aluminum nitride (AlN) or aluminum oxy-nitride (AlON) or hafnium oxide (HfO). Furthermore, as a non-limiting example of the present disclosure, the following choices are possible for the layers 16/18: AlN/Al₂O₃, Al₂O₃/AlN, AlON/Al₂O₃.

The first dielectric layer 16 has, for example, a thickness along the Z axis, comprised between 1 nm and 8 nm, for example 5 nm. In one embodiment, the value of this thickness is proportional to the negative threshold of the D-mode MIS-HEMT device 4 and may also depend on the dielectric constant of the chosen material. For example, by choosing AlN as the dielectric material, an adequate thickness is 4-5 nm.

The first insulating layer 18 is, for example, one of: aluminum oxide (Al₂O₃), hafnium oxide or, in general, an oxide that is removable with etchings (e.g., acid-based etchings) and selectively with respect to the material of the layer 16. The first insulating layer 18 has, for example, a thickness along the Z axis, comprised between 3 nm and 10 nm, for example 5 nm.

The second insulating layer 20 is for example made of silicon oxide (SiO₂) or silicon nitride (SiN), and has for example a thickness along the Z axis, comprised between 30 nm and 200 nm, for example 50 nm.

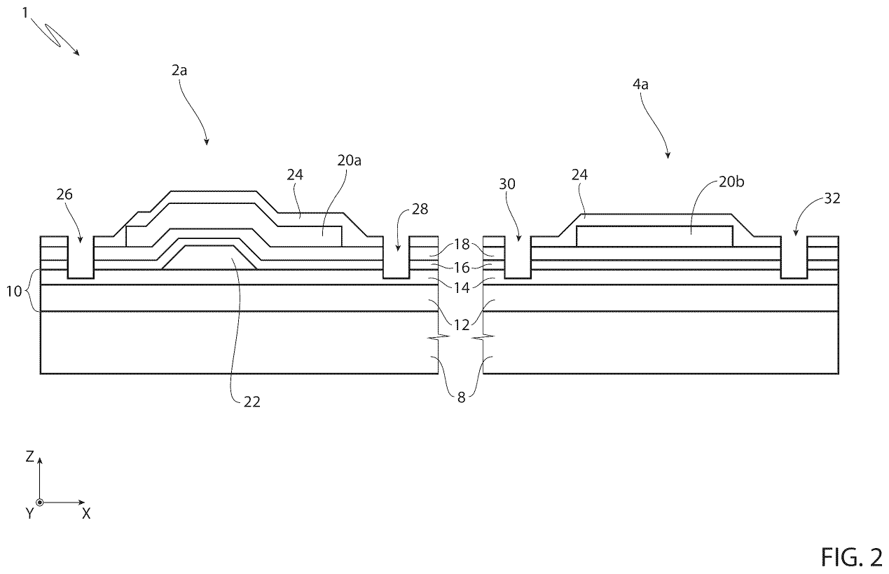

With reference to FIGS. 2 and 11, a step 102 of opening the source and drain contacts is performed, simultaneously carried out at the portions 2a and 4a of the die 1, respectively for the E-mode HEMT device 2 and for the D-mode MIS-HEMT device 4.

The step of opening the source and drain contacts comprises a step 102a of masked etching to pattern the second insulating layer 20, removing selective portions of the second insulating layer 20, for example through lithography followed by a chemical-physical etching, such as for example a Reactive Ion Etching (RIE). In this processing step, the first insulating layer 18 has the function of an etch stop layer, acting as an etch stop layer during the removal of the selective portions of the second insulating layer 20. In the embodiment wherein the first insulating layer 18 is not present, the etching of the second insulating layer 20 is a time etching designed in such a way as to completely remove the second insulating layer 20 where envisaged by the photolithographic process, exposing the underlying dielectric layer 16 without damaging it or damaging it in such a way as not to compromise its functional characteristics.

Regardless of the embodiment, a first portion 20a and a second portion 20b of the second insulating layer 20 are thus defined concurrently. The first portion 20a of the second insulating layer 20 extends in the first region 2a of the die 1, over and laterally to the doped gate region 22. In one embodiment, the first portion 20a extends, along the X axis, asymmetrically with respect to the doped gate region 22. In another embodiment, the first portion 20a extends, along the X axis, symmetrically with respect to the doped gate region 22.

In top view, on the XY plane, the first portion 20a has, for example, a quadrangular shape, with an extension along the X axis comprised between 1 μm and 3 μm and an extension along the Y axis at least equal to the corresponding extension of the doped gate region 22, or comprised between 50 μm and 1 mm.

The second portion 20b of the second insulating layer 20 extends in the second region 4a of the die 1. In top view, on the XY plane, the second portion 20b has, for example, a quadrangular shape, with an extension along the X axis comprised between 0.5 μm and 10 μm, preferably between 1 μm and 3 μm, and an extension along the Y axis comprised between 5 μm and 1 mm. These values may change depending on the voltage class of the device and are therefore not limiting of the present disclosure.

A step 102b of depositing a second dielectric layer 24 on the die 1 is then performed. The second dielectric layer 24 extends in the first 2a and the second 4a regions of the die 1, respectively over and in direct physical contact with the first and with the second portions 20a, 20b of the second insulating layer 20, and laterally to the first and second portions 20a, 20b, over and in direct physical contact with the first insulating layer 18 (alternatively, over and in direct physical contact with the dielectric layer 16 in the respective embodiment wherein the layer 18 is not present).

The second dielectric layer 24 is for example of silicon nitride (SiN) or silicon oxide (SiO2), and has for example a thickness along the Z axis, comprised between 50 nm and 300 nm, for example 80 nm.

A step 102c of masked etching is then performed, for example through RIE, to form a first source trench 26 and a first drain trench 28 in the first region 2a laterally and at a distance with respect to opposite sides, along the X axis, of the first portion 20a; and to form a second source trench 30 and a second drain trench 32 in the second region 4a laterally and at a distance with respect to opposite sides, along the X axis, of the second portion 20b.

The formation of the trenches 26, 28, 30 and 32 occurs, in one embodiment, concurrently, removing selective portions of the second dielectric layer 24, of the first insulating layer 18 (when present) and of the first dielectric layer 16, terminating in contact with the surface 14a of the heterostructure 10.

In another embodiment, the formation of the trenches 26, 28, 30 and 32 occurs concurrently, removing selective portions of the second dielectric layer 24, the first insulating layer 18 (if any), the first dielectric layer 16 and the heterostructure 10, terminating within the heterostructure 10, in particular within the barrier layer 14.

In another embodiment, the first source trench 26 and the first drain trench 28, the second source trench 30 and the second drain trench 32 terminate at the interface between the channel layer 12 and the barrier layer 14 (i.e., at the surface 12a).

In a further embodiment, the first source trench 26, the first drain trench 28, the second source trench 30 and the second drain trench 32 terminate within the channel layer 12 (for example, for a thickness lower than 15 nm along the Z axis starting from the surface 12a).

In a further embodiment, the trenches 26, 28, 30 and 32 may not be formed concurrently, but in respective manufacturing steps separate from each other, using respective masks.

In the embodiment wherein the first portion 20a extends asymmetrically on opposite sides along the X axis of the doped gate region 22, the distance between the first source trench 26 and the doped gate region 22 is smaller with respect to the distance between the first drain trench 28 and the doped gate region 22. The respective distances between the doped gate region 22 and the source 26 and drain 28 trenches depend on the type of use envisaged for the die 1, and may vary between 0.3 μm and 5 μm and in general are determined by the voltage class of the HEMT device, i.e. by the maximum voltage that may be applied to the drain of the component.

The second source trench 30 and the second drain trench 32 extend at respective distances with respect to opposite sides of the second portion 20b, for example comprised between 0.3 μm and 5 μm; in one embodiment, the second source trench 30 and the second drain trench 32 are symmetrical with respect to the second portion 20b. In a further embodiment, the second source trench 30 and the second drain trench 32 are asymmetrical with respect to the second portion 20b.

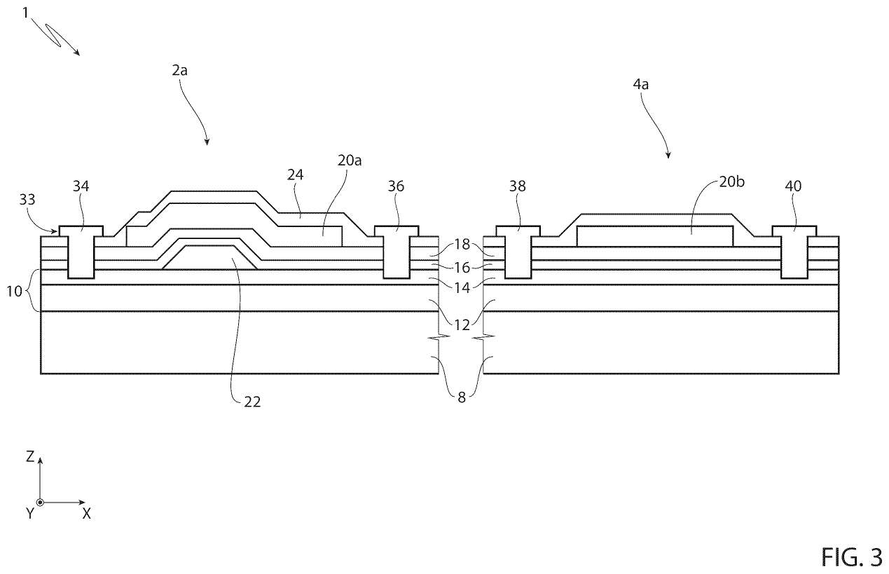

With reference to FIGS. 3 and 11, a step 104 of forming, in particular concurrently, source and drain contacts of the E-mode HEMT device 2 and the D-mode MIS-HEMT device 4 is now described.

Step 104 comprises a step 104a of depositing one or more metal layers 33 and a step 104b of patterning the one or more metal layers 33, in order to fill the source trenches 26, 30 and the drain trenches 28, 32. Step 104a includes, in particular, depositing the one or more metal layers 33 through evaporation or sputtering. In particular, the source trenches 26, 30 and the drain trenches 28, 32 are completely filled by means of such one or more metal layers 33. In particular, the one or more metal materials 33 allow to obtain an ohmic-type contact with the channel layer 12 and/or with the barrier layer 14 (with the 2DEG conduction layer placed at the interface between layer 14 and Layer 12).

The one or more metal layers 33 comprise one or more materials from among: titanium (Ti), tantalum (Ta), aluminum-copper (AlCu), titanium nitride (TiN), nickel (Ni), and gold (Au).

Step 104b includes, exemplarily and in a non-limiting manner, a lithography step followed by a selective etching of the one or more metal layers 33 or, alternatively, a lift-off process. Other patterning processes are possible. A source contact 34 and a drain contact 36 of the E-mode HEMT device 2 are obtained, at the end of step 104b, in the first source trench 26 and in the first drain trench 28, respectively. Concurrently, a source contact 38 and a drain contact 40 of the D-mode MIS-HEMT device 4 are obtained, in the second source trench 30 and in the first drain trench 32, respectively.

Then, a step 104c, that is optional, of rapid thermal treatment (RTP) is performed, for example at a temperature comprised between 400° C. and 900° C., to favour the formation of ohmic contacts between the source contacts 34, 38 and the channel layer 12 and/or the barrier layer 14, and between the drain contacts 36, 40 and the channel layer 12 and/or the barrier layer 14.

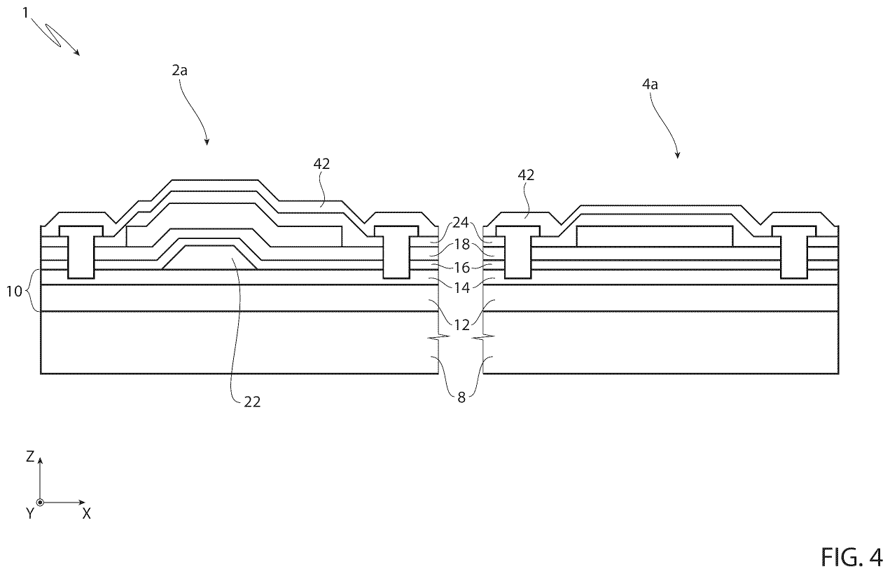

With reference to FIGS. 4 and 11, a step 106 of depositing a third dielectric layer 42 is performed, for example through chemical vapor deposition (CVD) or plasma-enhanced (PE) chemical vapour deposition or thermal deposition or ALD. The third dielectric layer 42 extends over the second dielectric layer 24, the source contacts 34, 38 and the drain contacts 36, 40, and in direct physical contact with the second dielectric layer 24, the source contacts 34, 38 and the drain contacts 36, 40. In particular, the third dielectric layer 42 completely covers the source contacts 34, 38 and the drain contacts 36, 40.

The third dielectric layer 42 is for example of silicon nitride (SiN) or silicon oxide, and has for example a thickness, along the Z axis, comprised between 50 nm and 200 nm, for example 70 nm.

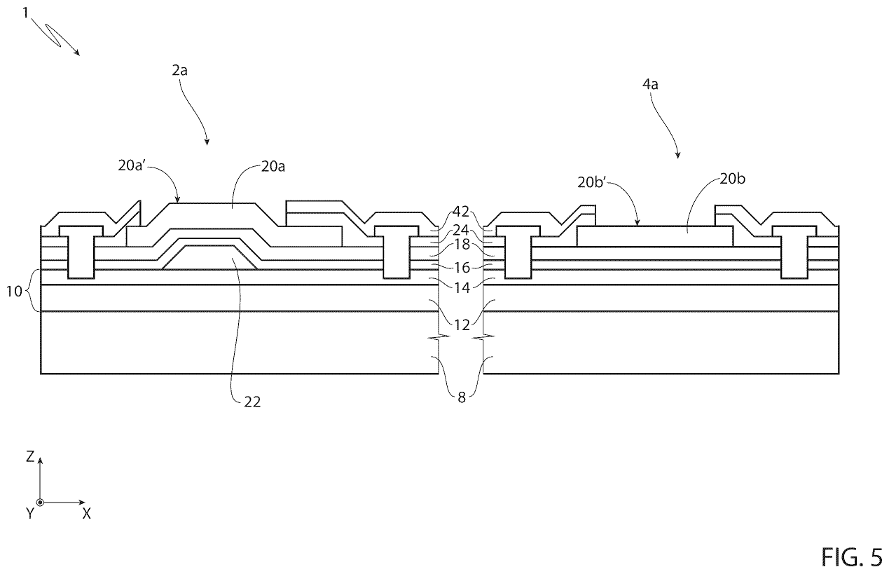

With reference to FIGS. 5 and 11, a step 108 of selective etching is performed, for example through lithography and etching (e.g., RIE), of the third dielectric layer 42 and the second dielectric layer 24, thus exposing at least partly a surface 20a′ of the first portion 20a at the doped gate region 22, and at least partly a surface 20b′ of the second portion 20b, at a central region of the second portion 20b.

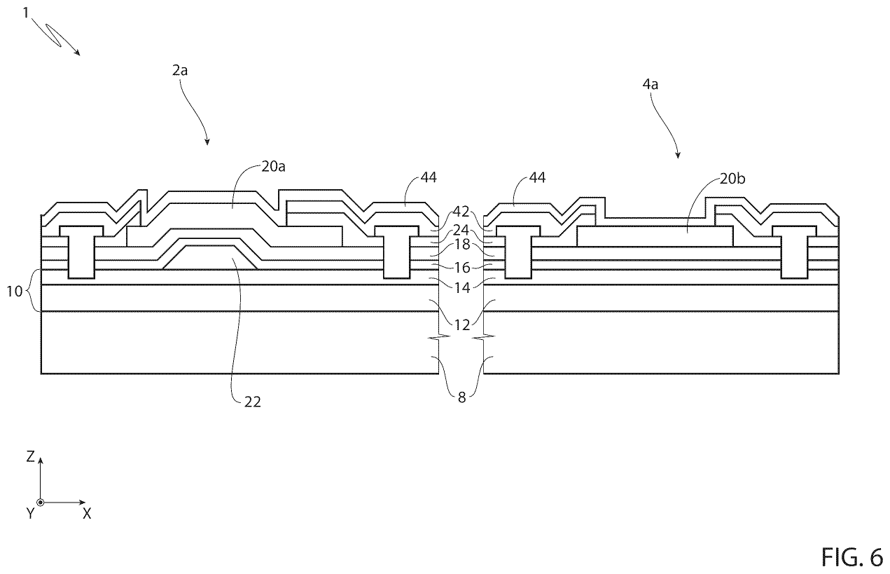

With reference to FIGS. 6 and 11, a step 110, that is optional, of depositing a third insulating layer 44 is performed, for example through CVD. The third insulating layer 44 extends in continuity on the third dielectric layer 42 and on the surfaces 20a′, 20b′ of the second insulating layer 20, in direct physical contact with the third dielectric layer 42 and with the surfaces 20a′, 20b′. The third insulating layer 44 is, in particular, of the same material as the second insulating layer 20, for example of silicon oxide (SiO₂) or SiN, and has for example a thickness along the Z axis, comprised between 100 nm and 200 nm, for example 150 nm. In one embodiment, the second insulating layer 20 and the third insulating layer 44 are of a same material, for example SiO₂, and together form, where adjacent to each other (i.e. above the doped gate region 22), a single insulating layer.

It should be noted that, advantageously, steps 100-110 of the process described allow the number of lithographic masks necessary for the manufacture of the die 1 to be minimized.

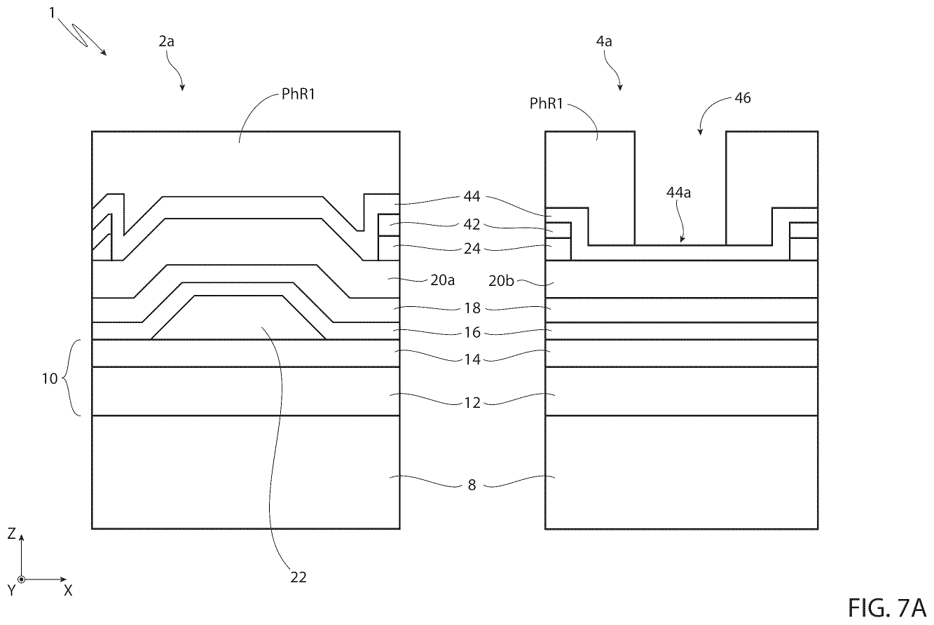

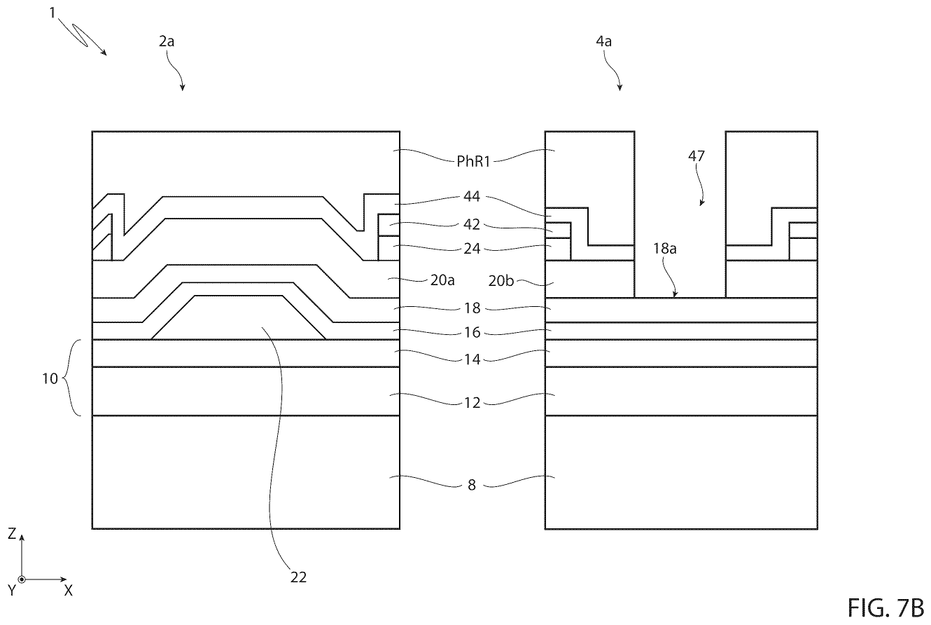

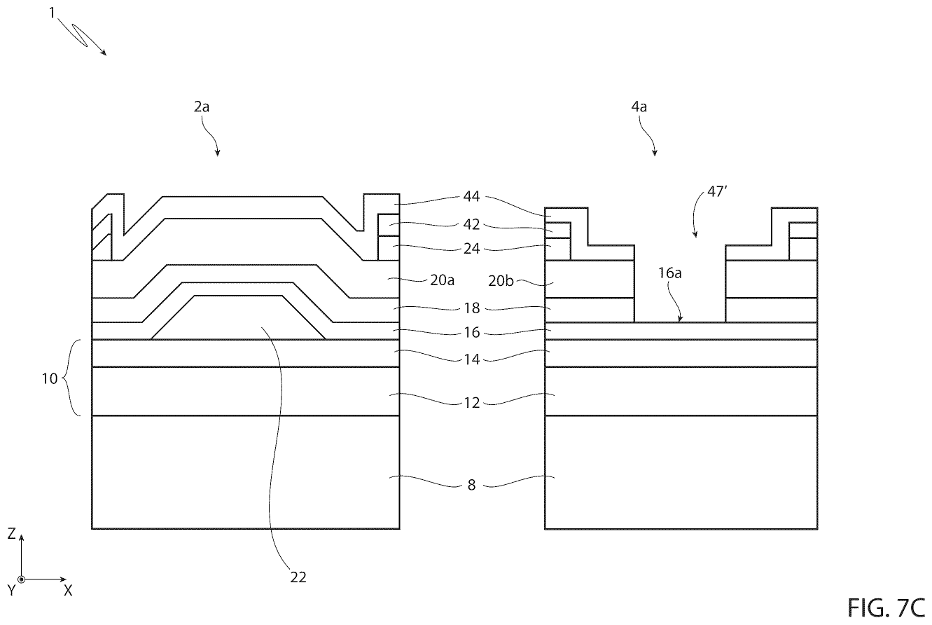

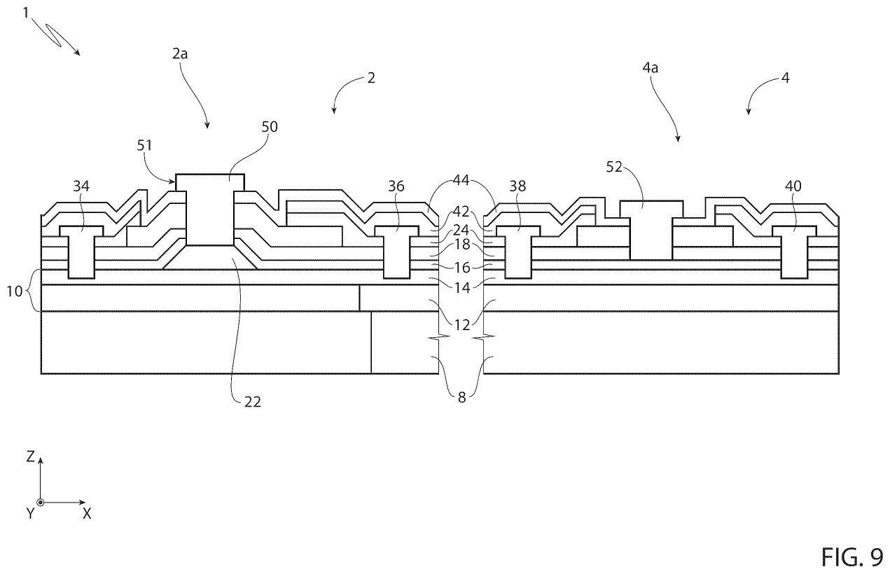

With reference to FIGS. 7A-7C and 11, a step 112 of opening a first gate trench 47′ is now described adapted to accommodate a gate contact 52 (illustrated hereinafter with reference to FIG. 9) of the D-mode MIS-HEMT device 4. With respect to FIGS. 1-6, FIGS. 7A-7C illustrate only part of the regions 2a and 4a, limitedly to regions of interest for the process described.

With reference to FIG. 7A, step 112a, a photoresist layer PhR1 is deposited on the die 1; the photoresist layer PhR1 is patterned by means of a photolithographic process to form a trench 46 that extends, along the Z axis, throughout the entire thickness of the photoresist layer PhR1, until it reaches the third insulating layer 44. In particular, the trench 46 is formed at a portion of the third insulating layer 44 that extends in direct contact with the second portion 20b of the second insulating layer 20 in the region 4a, exposing a surface 44a of the third insulating layer 44. It should be noted that, in step 112a, the portion of the third insulating layer 44 that covers the doped gate region 22 is protected by the photoresist layer PhR1.

With reference to FIG. 7B, a step 112b of etching is performed to selectively remove, through the trench 46, the third insulating layer 44 and the second insulating layer 20. The etching of step 112b stops on the first insulating layer 18. In the embodiment wherein the third insulating layer 44 and the second insulating layer 20 are of silicon oxide and the first insulating layer 18 is of aluminum oxide, step 112b of etching is carried out for example through RIE exploiting a mixture of difluoromethane (CH₂F₂), tetrafluoromethane (CF₄) and helium (Hₑ), thus obtaining a dry etching that selectively removes the sole silicon oxide, without removing the aluminum oxide of the first insulating layer 18. In other words, the first insulating layer 18 acts as an etch stop layer. A trench 47 is thus obtained that extends along the Z axis in the third insulating layer 44, in the second insulating layer 20 and terminates on the first insulating layer 18, exposing a portion 18a of the surface of the first insulating layer 18.

With reference to FIG. 7C, step 112c, the photoresist layer PhR1 is removed, for example through oxygen plasma etching or another dry removal method.

After the removal of the photoresist PhR1, a step 112d of wet etching is performed through the trench 47, to selectively remove the first insulating layer 18 at the surface portion 18a, terminating on the first dielectric layer 16. For example, an etching is performed through dilute hydrofluoric acid (HF) or through buffered oxide etch (BOE).

The chemistry used for the etching of step 112d allows the aluminum oxide of the first insulating layer 18 to be selectively removed without removing or damaging the aluminum nitride of the first dielectric layer 16. In other words, the first dielectric layer 16 is adapted to operate as an “etch stop layer” for the etching of step 112c.

In this manner a first gate trench 47′ is obtained that extends, along the Z axis, in the third insulating layer 44, in the second insulating layer 20 and in the first insulating layer 18, terminating on the first dielectric layer 16. A surface portion 16a of the first dielectric layer 16 is exposed through the first gate trench 47′. It should be noted that the surface 16a exposed through the first gate trench 47′, in all steps 100-112b of the described process, has remained protected by the first insulating layer 18. Therefore, the first dielectric layer 16 has not undergone damage induced, for example, by the RIE processes (or similar etching processes) of steps 102a, 102b and 112d. The first dielectric layer 16 is therefore particularly suitable for being used as a gate dielectric for the D-mode MIS-HEMT device 4.

In the embodiment wherein the first insulating layer 18 is not present, the trench 47′ extends along the Z axis through the third insulating layer 44 and the second insulating layer 20, and terminates on the first dielectric layer 16, exposing the surface portion 16a of the first dielectric layer 16. As previously described, in the absence of the insulating layer 18, the etching of the second insulating layer 20 of step 102a is a time etching designed in such a way as to completely remove the second insulating layer 20 where envisaged by the photolithographic process, exposing the underlying dielectric layer 16 without damaging it or damaging it in such a way as not to compromise its functional characteristics.

Furthermore, for all the embodiments described, it should be noted that the barrier layer 14, has not in turn undergone damage from RIE (or similar) etchings and from the etching of step 112d, being protected by the dielectric layer 16. In this manner, the formation of dangling bonds and Ga-O bonds on the surface 14a of the barrier layer 14 is prevented, thus avoiding the accumulation of negative charges that lead to a degradation of the mobility of the electrons in the 2DEG and to a reduced density of the 2DEG under the gate contact 52 of the D-mode MIS-HEMT device 4. A decrease in the performances of the D-mode transistors is thus prevented, in particular as to the resistance R_{ON} of the conductive channel.

Steps 112c and 112d, as previously described, may be exchanged with each other, i.e. step 112d is performed before step 112c. In this context, a HF buffer or photoresist selective chemistry solution is used during step 112d.

The first gate trench 47′ is at a distance from the source contact 38, along the X axis, comprised between 0.5 μm and 3 μm, and at a distance from the drain contact 40, along the X axis, comprised between 0.5 μm and 4 μm. In one embodiment, the first gate trench 47′ is equidistant from the source contact 38 and the drain contact 40 of the D-mode MIS-HEMT device 4. In a further embodiment, the first gate trench 47′ is not equidistant from the source contact 38 and the drain contact 40 of the D-mode MIS-HEMT device 4 (for example, the distance of the gate terminal from the drain terminal is greater than the distance of the gate terminal from the source terminal).

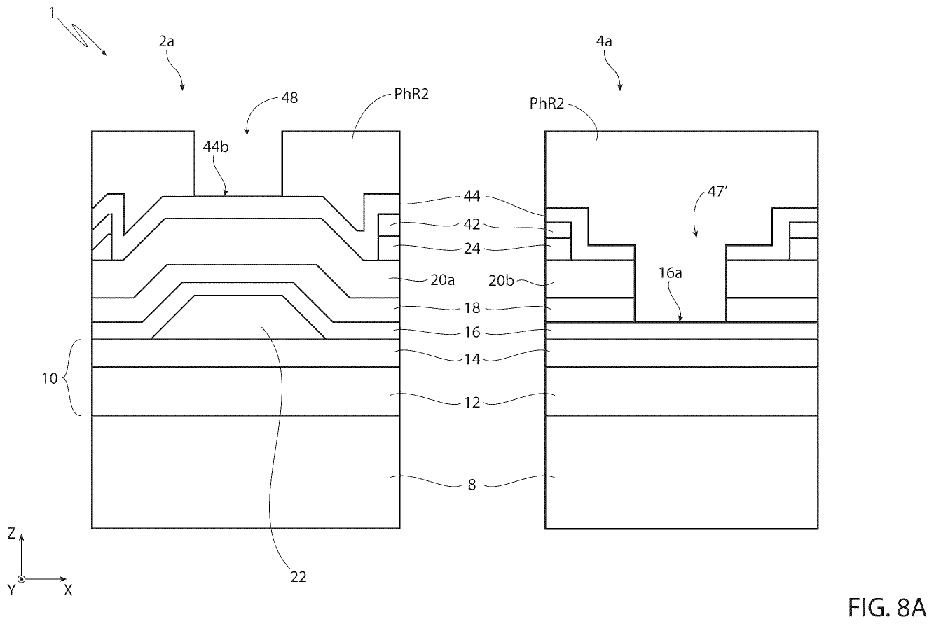

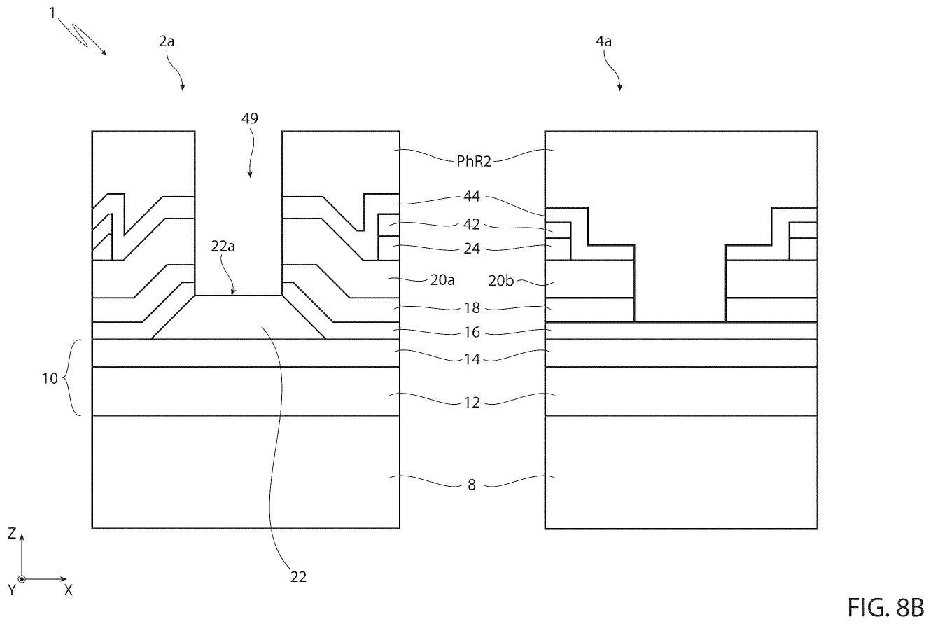

With reference to FIGS. 8A, 8B and 11, in a step 114 a second gate trench 49 is formed adapted to accommodate a gate contact 50 of the E-mode HEMT device 2. FIGS. 8A and 8B illustrate the same portions of regions 2a and 4a as in FIGS. 7A-7C, in particular following the manufacturing steps of FIGS. 7A-7C.

With reference to FIG. 8A, step 114a, the formation of the second gate trench 49 of the E-mode HEMT device 2 envisages a step of depositing a photoresist layer PhR2 on the die 1 and a respective photolithographic process to form a trench 48 in the photoresist layer PhR2.

The trench 48 extends, along the Z axis, throughout the entire thickness of the photoresist layer PhR2, exposing a surface 44b of the third insulating layer 44, at the doped gate region 22. It should be noted that in step 114a the surface 16a of the first dielectric layer 16, previously exposed through the first gate trench 47′, is protected by the photoresist layer PhR2.

With reference to FIG. 8B, step 114b, an etching, in particular a dry etching, is performed to remove, through the trench 48, selective portions of the third insulating layer 44, the second insulating layer 20, the first insulating layer 18 (if any) and the first dielectric layer 16, exposing a surface of the doped gate region 22. A second gate trench 49 is thus formed which extends through the third insulating layer 44, the second insulating layer 20, the first insulating layer 18 (if any) and the first dielectric layer 16, and terminates on a surface 22a of the doped gate region 22.

Alternatively to what has been illustrated in FIG. 8B, according to a further embodiment, the dielectric layer 16 is not removed within the gate trench 49. In this case, the manufacturing process will lead to the formation of an E-mode MIS-HEMT device in the first region 2a.

The photoresist layer PhR2 is then removed (step 114c), for example through oxygen plasma etching or other dry removal (wet cleaning treatments may also be performed successively).

It is evident that steps 114a-114c of FIGS. 8A and 8B may be performed prior to steps 112a-112d of FIGS. 7A-7C. In this case, therefore, the opening of the second gate trench 49 is performed before the opening of the first gate trench 47′; during the step of forming the first gate trench 47′, the surface 22a of the doped region 22, exposed through the second gate trench 49, is protected by the photoresist used for the formation of the first gate trench 47′ (similarly to what has been described above for step 114).

In a further embodiment, the trenches 47′ and 49 are formed concurrently performing, simultaneously for both trenches 47′ and 49, the steps of removing the second and the third insulating layers 20, 44 and, successively, the first insulating layer 18. In this context, the removal of the dielectric layer 16 from the surface of the doped gate region 22, during the formation of the trench 49, is optional.

In this embodiment, the formation of the trench 47′ and the trench 49 envisages a step of masking by means of photoresist the die 1 except for the regions of the same wherein the trenches 47′ and 49 are desired to be formed (i.e. at the regions wherein the gate terminals of the devices 2 and 4 will be formed).

One or more etching steps (for example, a dry etching) are then performed of the third insulating layer 44 and the second insulating layer 20 in both regions 2a, 4a, exposing the first insulating layer 18 (if any).

A step of removing the photoresist mask from the die 1 is then performed.

Then, the first insulating layer 18 exposed following the removal of the second and the third insulating layers 20, 44 is removed. The step of removing the first insulating layer 18 is, for example, performed with an unmasked wet etching. A surface portion of the dielectric layer 16 is thus exposed in both trenches 47′, 49.

In case the dielectric layer 16 remains in both trenches 47′ and 49, the successive manufacturing steps (FIGS. 9 and 10) will lead to the formation of respective E-mode MIS-HEMT and D-mode MIS-HEMT devices.

The removal of the dielectric layer 16 at the first region 2a (i.e. above the doped gate region 22) is however possible forming, following the process described above, a further mask (e.g., of photoresist) that fills the trench 47′ in the second region 4a and allows to selectively remove the portion of the dielectric layer 16 exposed through the trench 49 at the first region 2a.

With reference to FIGS. 9 and 11, a step 116 of concurrently forming gate contacts 50, 52 of the E-mode HEMT device 2 and D-mode MIS-HEMT device 4, respectively, is now described. This manufacturing step applies regardless of the embodiment chosen for forming the trenches 47′ and 49.

Step 116 comprises completely filling the second gate trench 49 and the first gate trench 47′ by means of a step 116a of depositing a metal layer 51 and a step 116b of patterning the metal layer 51. Step 116a includes depositing, for example through evaporation or sputtering, metal material, completely filling the gate trenches 49 and 47′.

The metal layer 51 comprises for example one of: titanium (Ti), tantalum (Ta), aluminum-copper (AlCu). Alternatively, the filling of the gate trenches 47′ and 49 may include a plurality of superimposed metal layers such as for example a TiN/AlCu/TiN stack.

Step 116b includes a lithography followed by a selective etching of the metal layer 51, or alternatively a lift-off process. At the end of step 116b of patterning, the gate contact 50 of the E-mode HEMT device 2 and the gate contact 52 of the D-mode MIS-HEMT device 4 are thus concurrently obtained, in the second gate trench 49 and in the first gate trench 47′, respectively. In particular, a Schottky diode is generated between the gate contact 50 of the E-mode HEMT device 2 and the doped gate region 22. The gate contact 52 instead acts as a biasable metal contact in the metal/dielectric/semiconductor stack formed respectively by the gate contact 52, the first dielectric layer 16 and the barrier layer 14 in the D-mode MIS-HEMT device 4.

Therefore, the E-mode HEMT device 2 and the D-mode MIS-HEMT device 4 are thus obtained, co-integrated on the die 1.

With reference to FIG. 10, a further embodiment of the present disclosure is now described, wherein the E-mode HEMT device 2 is dedicated to power applications. In this embodiment, after step 108 and before step 110, a step 109 of forming a field plate 54 is performed.

In detail, after step 108, a field plate metal layer is deposited (step 109a), on the die 1, on the second insulating layer 20 and on the third dielectric layer 42. The field plate metal layer extends with continuity on the second insulating layer 20 and on the third dielectric layer 42, in direct physical contact with the second insulating layer 20 and with the third dielectric layer 42.

Then, step 109b, a patterning of the field plate metal layer is carried out, for example through lithography and etching, forming the field plate 54 of FIG. 10. The field plate 54 extends partly on the portion 20a of the second insulating layer 20 and partly on the third dielectric layer 42, between the gate region 22 and the drain contact 36, at a distance from both the gate region 22 and the drain contact 36.

The field plate 54 is adapted, during the use of the E-mode HEMT device 2, to be biased to an electric potential equal to the electric potential of the source contact 34, and has the purpose of modifying the existing electric field, in particular to make it more uniform during the operation of the E-mode HEMT device 2. Furthermore, the presence of the field plate 54 allows an increase in the gain of the E-mode HEMT device 2 compared to a HEMT device wherein a corresponding field plate is absent.

During step 109, similarly to what has been described with reference to the E-mode HEMT device 2, a corresponding field plate for the D-mode MIS-HEMT device (not illustrated) may be manufactured concurrently.

The field plate 54 is of a conductive material such as for example titanium nitride, titanium, aluminum, or platinum, or nickel, or copper, or other metal material.

With reference to FIG. 11, following step 116, an optional step of depositing passivating or insulating material (for example, SiN) is also performed above the first region 2a and the second region 4a, for protecting and electrically insulating the same. Electrical contact regions are formed through the passivating layer for biasing the source contacts 34, 38, the drain contacts 36, 40 and the gate contacts 50, 52, in a manner known per se.

Finally, it is clear that modifications and variations may be made to what has been described and illustrated here without thereby departing from the scope of the present disclosure, as defined in the attached claims.

For example, the die 1 may accommodate a plurality of E-mode HEMT devices 2 (and/or E-mode MIS-HEMT devices), and a plurality of D-mode MIS-HEMT devices 4.

From what has been previously exposed, the advantages that the present disclosure affords are evident.

In particular, E-mode and D-mode devices are provided on a same die in a single process flow, with only one additional mask for the opening of the gate contacts to be carried out in distinct process steps for E-mode devices and for D-mode devices.

Furthermore, the D-mode MIS-HEMT device 4, having the dielectric layer 16 interposed between the gate contact 52 and the barrier layer 14, has, in use, a more stable turn-on threshold voltage than D-mode HEMT devices wherein the gate terminal is in direct contact with the barrier layer. The AlN layer protects the surface of the AlGaN layer from plasma etchings and wet removals necessary for opening the contact; a D-mode HEMT device typically operates at lower gate voltages; therefore, introducing an oxide layer makes its threshold voltage more negative, which is typically proximate to 0 (between −0.4 V and −0.9 V). In this manner, even at gate voltages that are weakly positive or equal to 0V, the channel is conductive with a design that allows saving space.

Furthermore, it is noted that the dielectric layer 16 has advantageously the dual function of gate dielectric for the D-mode MIS-HEMT device 4 and passivation layer for the doped gate region 22 of the E-mode HEMT device 2.

1. A method for manufacturing a semiconductor die including an E-mode HEMT or E-mode MIS-HEMT device at a first region of the semiconductor die and a D-mode MIS-HEMT device at a second region of the semiconductor die, the first region and the second region being at a distance from each other, wherein the method comprises:
forming a heterostructure on a substrate of the semiconductor die, at both the first region and the second region;
forming, on the heterostructure, a doped gate region of the E-mode HEMT or E-mode MIS-HEMT device, at the first region;
forming a dielectric layer in the first region on the heterostructure and on the doped gate region and, concurrently, in the second region on the heterostructure, the dielectric layer being of a first material;
forming a first insulating layer on the dielectric layer, at the first region and the second region, of a second material that may be selectively etched with respect to the first material;
forming a first gate opening by etching the first insulating layer throughout an entire thickness and exposing the dielectric layer underlying, at the second region;
forming a second gate opening by etching the first insulating layer throughout the entire thickness, at the doped gate region; and
forming a gate conductive terminal of the D-mode MIS-HEMT device in the first gate opening and, concurrently, forming a respective gate conductive terminal of the E-mode HEMT or E-mode MIS-HEMT device in the second gate opening.

2. The method of claim 1, wherein forming the second gate opening further comprises, after etching the first insulating layer, etching, throughout the entire thickness, the dielectric layer exclusively at the doped gate region, exposing a portion of the doped gate region.

3. The method of claim 1, further comprising forming, concurrently at the first region and the second region of the semiconductor die, a second insulating layer on the first insulating layer and at least partly superimposed on the doped gate region;
wherein the second insulating layer is of a third material that may be selectively etched with respect to the second material;
wherein forming the first gate opening further comprising etching the second insulating layer throughout the entire thickness, at the second region, partly exposing the first insulating layer; and
wherein forming the second gate opening further comprising etching the second insulating layer throughout the entire thickness, at the first region and the doped gate region, partly exposing the first insulating layer.

4. The method of claim 1, wherein forming the first gate opening is performed before forming the second gate opening and comprises:
depositing a first mask layer over the semiconductor die concurrently at the first region and the second region; and
removing selective portions of the first mask layer exclusively at the second region, wherein etching the first insulating layer for forming the first gate opening being performed at the selective portions removed of the first mask layer,
wherein forming the second gate opening comprises:
depositing a second mask layer over the semiconductor die concurrently at the first region and the second region and within the first gate opening; and
removing selective portions of the second mask layer exclusively at the doped gate region, wherein etching the first insulating layer forming the second gate opening being performed at the selective portions removed of the second mask layer.

5. The method of claim 1, wherein forming the second gate opening is performed before forming the first gate opening and comprises:
depositing a first mask layer over the semiconductor die concurrently at the first region and the second region;
removing selective portions of the first mask layer exclusively at the doped gate region, wherein etching the first insulating layer forming the second gate opening being performed at the selective portions removed of the first mask layer;
wherein forming the first gate opening comprises:
depositing a second mask layer over the semiconductor die concurrently at the first region and the second region and within the second gate opening; and
removing selective portions of the second mask layer exclusively at the second region, wherein etching the first insulating layer forming the first gate opening being performed at the selective portions removed of the second mask layer.

6. The method of claim 1, further comprising:
forming first conduction terminals of the E-mode HEMT or E-mode MIS-HEMT device, including:
forming a first trench and a second trench at respective opposite sides of the doped gate region removing selective portions of the first insulating layer and the dielectric layer, reaching the heterostructure;
filling the first trench and the second trench with at least one first metal layer; and
concurrently, forming second conduction terminals of the D-mode MIS-HEMT device, including:
forming a third trench and a fourth trench in the second region of the semiconductor die removing selective portions of the first insulating layer and of the dielectric layer, reaching the heterostructure; and
filling the third trench and the fourth trench with the at least one first metal layer.

7. The method of claim 6, wherein forming the first conduction terminals and the second conduction terminals is performed before forming the first gate opening and forming the second gate opening;
wherein the first conduction terminals of the E-mode HEMT or E-mode MIS-HEMT device include a source terminal and a drain terminal; and
wherein the method further comprises forming a field plate conductive layer over the first insulating layer between the doped gate region and the drain terminal.

8. The method of claim 3, wherein etching the second insulating layer to form the first gate opening is performed exclusively at the second region; and
wherein etching the second insulating layer to form the second gate opening is performed exclusively at the first region.

9. The method according to claim 1, wherein forming the gate conductive terminal of the D-mode MIS-HEMT device and the gate conductive terminal of the E-mode HEMT or E-mode MIS-HEMT device comprises depositing conductive material in the first gate opening until it reaches and contacts the dielectric layer and, concurrently, depositing the conductive material in the second gate opening until it reaches and contacts the doped gate region.

10. A semiconductor die including an E-mode HEMT or E-mode MIS-HEMT device at a first region of the semiconductor die and a D-mode MIS-HEMT device at a second region of the semiconductor die, the first region and second region being at a distance from each other, the semiconductor die comprising:
a heterostructure on a substrate of the semiconductor die, at both the first region and the second region;
a doped gate region of the E-mode HEMT or E-mode MIS-HEMT device on the heterostructure, at the first region;
a dielectric layer on the heterostructure and on the doped gate region at the first region and on the heterostructure at the second region, the dielectric layer being of a first material;
a first insulating layer on the dielectric layer, at the first region and the second region, of a second material which may be selectively etched with respect to the first material;
a gate conductive terminal of the D-mode MIS-HEMT device, extending through the first insulating layer and in direct contact with the dielectric layer at the second region; and
a respective gate conductive terminal of the E-mode HEMT or E-mode MIS-HEMT device, extending through the first insulating layer and the dielectric layer, in electrical contact with the doped gate region.
